(19) United States
(12) Patent Application Publication
(10) Pub. No.: US 2013/0113084 A1
(43) Pub. Date: May 9, 2013

(54) SEMICONDUCTOR SUBSTRATE WITH MOLDED SUPPORT LAYER

(71) Applicants: Roden R. Topacio, Markham (CA); Neil McLellan, Austin, TX (US); Yip Seng Low, Thornhill (CA); Jianguo Li, Scarborough (CA)

(72) Inventors: Roden R. Topacio, Markham (CA); Neil McLellan, Austin, TX (US); Yip Seng Low, Thornhill (CA); Jianguo Li, Scarborough (CA)

(21) Appl. No.: 13/289,761

(22) Filed: Nov. 4, 2011

(51) Int. Cl. H01L 23/498; H01L 21/56

(52) U.S. Cl. 257/621; 438/108; 257/E23.067; 257/E21.504

(57) ABSTRACT

Various semiconductor substrates and methods of processing the same are disclosed. In one aspect, a method of manufacturing is provided that includes mounting a first semiconductor chip on a side of a first substrate. The first substrate has at least one thru-silicon-via. An insulating layer is molded on the side of the first substrate. The insulating layer provides a support structure to enable handling of the first substrate.

### BACKGROUND OF THE INVENTION

1. Field of the Invention

This invention relates generally to semiconductor processing, and more particularly to thru-silicon-via substrates and methods of making and processing the same.

2. Description of the Related Art

Processing and handling of thin thru-silicon-via (TSV) wafers and TSV dice present several technical challenges. In one conventional technique for processing a conventional TSV wafer, a carrier wafer needed to support the TSV wafer during various process steps, such as wafer thinning and solder ball attach. The thinning process is used to expose ends of the TSVs in anticipation of the solder ball attach. A typical carrier wafer is constructed of glass and attached to the TSV wafer by an adhesive. Following various process steps, the carrier wafer must be removed. There are material and time costs associated with the usage of carrier wafers.

After the carrier wafer is removed but before individual die are singulated, another type of supporting wafer or substrate must be applied to the underside of the TSV wafer. This second supporting wafer is used to support the TSV wafer during singulation, and must be removed after singulation, again resulting in material and time costs.

The singulated portions of the TSV wafer are subsequently mounted to another substrate and an underfill is dispensed. Since the conventional singulated portion of the TSV wafer typically has exposed topside conductor pads, the conventional underfill dispensing process can result in underfill creeping up the sides of the portion and contaminating the conductor pads.

Finally, one or more semiconductor chips are mounted to the topside of the singulated portion of the TSV wafer and underfill is applied using capillary action. Since adequate positioning of the underfill relies on capillary action, the spacing between adjacent semiconductor chips must be above certain limits. This can create barriers to device miniaturization.

In many of the steps just described, a very thin silicon substrate must be moved about or otherwise physically manipulated. These movements are conventionally carried out with little to support the delicate substrates.

The present invention is directed to overcoming or reducing the effects of one or more of the foregoing disadvantages.

### SUMMARY OF EMBODIMENTS OF THE INVENTION

In accordance with one aspect of an embodiment of the present invention, a method of manufacturing is provided that includes mounting a first semiconductor chip on a side of a first substrate. The first substrate has at least one thru-silicon-via. An insulating layer is molded on the side of the first substrate. The insulating layer provides a support structure to enable handling of the first substrate.

In accordance with another aspect of an embodiment of the present invention, a method of manufacturing is provided that includes forming a first group of thru-silicon-vias in a first portion of a semiconductor substrate and second group of thru-silicon-vias in a second portion of the semiconductor substrate. The semiconductor substrate has a side. A first semiconductor chip is mounted on the side and first portion of the semiconductor substrate. A second semiconductor chip is mounted on the side and second portion of the semiconductor substrate. An insulating layer is molded on the side of the semiconductor substrate. The insulating layer provides a support structure to enable handling of the semiconductor substrate.

In accordance with another aspect of an embodiment of the present invention, an apparatus is provided that includes a substrate that has at least one thru-silicon-via, a side and a dicing street. A first semiconductor chip is coupled to the side of the substrate on a side of the dicing street and a second semiconductor chip is coupled to the side on an opposite side of the dicing street. An insulating layer is on the side of the substrate and spans across the dicing street. The insulating layer serves as an underfill for the first and second semiconductor chips and provides a support structure to enable handling of the substrate.

### BRIEF DESCRIPTION OF THE DRAWINGS

The foregoing and other advantages of the invention will become apparent upon reading the following detailed description and upon reference to the drawings in which:

FIG. 1 is a sectional view of an exemplary embodiment of a conventional substrate;

FIG. 2 is a sectional view like FIG. 1 but depicting conventional via hole formation;

FIG. 3 is a sectional view like FIG. 2 but depicting conventional via hole liner layer formation;

FIG. 4 is a sectional view like FIG. 3 but depicting conventional via and interconnect layer formation;

FIG. 5 is a sectional view like FIG. 4 but depicting conventional carrier wafer application;

FIG. 6 is a sectional view like FIG. 5, but depicting conventional wafer thinning;

FIG. 7 is a sectional view like FIG. 6, but depicting conventional solder ball attach;

FIG. 8 is a sectional view like FIG. 7, but depicting conventional supporting tape application;

FIG. 9 is a sectional view like FIG. 8, but depicting conventional carrier wafer removal and dicing tape application;

FIG. 10 is a sectional view like FIG. 9, but depicting conventional device singulation;

FIG. 11 is a sectional view depicting conventional mounting and underfill application for the singulated device;

FIG. 12 is a sectional view like FIG. 11, but depicting the mounted device after underfill application;

FIG. 13 is a sectional view like FIG. 11, but depicting conventional chip stacking and underfill application;

FIG. 14 is a sectional view of an exemplary embodiment of a substrate with multiple semiconductor chips mounted thereon;

FIG. 15 is a sectional view like FIG. 14, but depicting exemplary molding of an insulating layer to the substrate;

FIG. 16 is a sectional view like FIG. 15, but depicting exemplary substrate thinning, conductor structure and dicing tape application;

FIG. 17 is a sectional view like FIG. 16, but depicting exemplary singulation of devices from the substrate;

FIG. 18 is a sectional view depicting exemplary mounting of a singulated device and underfill application;

FIG. 19 is a sectional view like FIG. 18, but depicting the mounted device after underfill application; and

FIG. 20 is a pictorial view of an exemplary singulated device exploded from an electronic device.

### DETAILED DESCRIPTION OF SPECIFIC EMBODIMENTS

Various substrates incorporating a molded layer that serves both as a semiconductor chip underfill and as a supporting layer are disclosed. In one arrangement, multiple semiconductor chips are mounted to a substrate, which may be a semiconductor wafer or other substrate. The substrate includes one or more thru-silicon vias. A molded layer is applied to the substrate. The molding process forces the insulating material between the semiconductor chips and the substrate and across expanses between adjacent chips. Additional details will now be described.

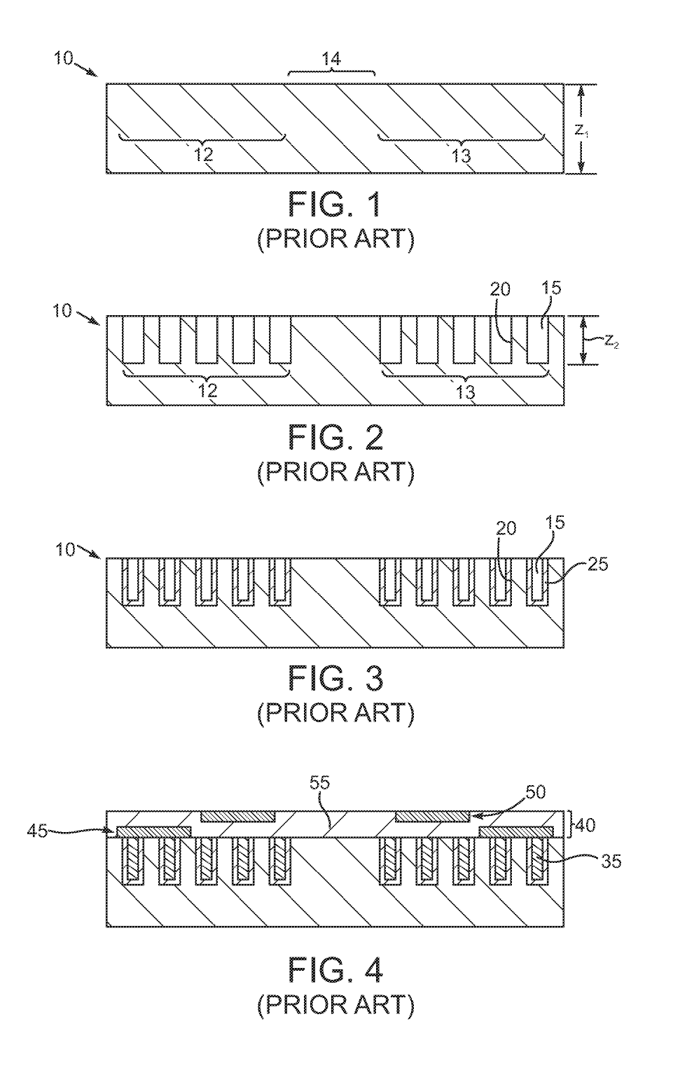

In the drawings described below, reference numerals are generally repeated where identical elements appear in more than one figure. Turning now to the drawings, and in particular to FIG. 1, therein is shown a sectional view of an exemplary embodiment of a conventional substrate 10. In this illustrative embodiment, the substrate 10 may be a semiconductor wafer that may include device portions or regions 12 and 13 that are ultimately singulated into individual semiconductor devices or chips. Only two portions 12 and 13 are depicted for simplicity of illustration. However, it should be understood that the substrate 10 may include many more than just the two regions 12 and 13. Here the portions 12 and 13 are separated laterally by a dicing street 14. The substrate 10 may be composed of a variety of materials such as silicon, germanium, gallium arsenide, other semiconductor substrate or even insulating materials. The substrate 10 may be provided with some initial thickness z₁ that may be in the range of about 700 to 800 microns. However as noted below, if TSV formation is envisioned, the substrate 10 may undergo a thinning process.

Next and as depicted in FIG. 2, the substrate 10 will undergo a material removal process in order to establish plural via holes 15, some of which are positioned in the portion 12 and others in the portion 13. The via holes 15 may have a generally, though not necessarily, round footprint when viewed from above and a depth z₂ of about 80 to 150 microns. If fabricated with a round footprint, the via holes 15 may have a diameter of about 10 to 15 microns and preferably about 12 microns. It should be understood that the number and arrangement of the via holes 15 is subject to great variety. Here, only a few of the via holes 15 are depicted for simplicity of illustration. The material removal process to establish the via holes 15 may be accomplished using a chemical etch with or without plasma enhancement. Directional etching to establish relatively vertical sidewalls 20 may be used. For example, reactive ion etching using CF₄ alone or with O₂ and endpoint detection by timing. Optionally, laser drilling could be used to establish the via holes 15.

It is desirable to protect the sidewalls 20 of the via holes 15 with one or more materials in order to prevent the later-formed conductive vias from shorting into the substrate material and to prevent the migration of materials back and forth across the sidewalls which might impede the performance of the later formed conductive vias. Accordingly and as depicted in FIG. 3, the sidewalls 20 may be lined with an insulating layer 25 composed of silicon dioxide or other insulating materials. If composed of silicon dioxide, thermal oxidation or chemical vapor deposition (CVD) may be used. The insulating layer 25 may have a thickness of about 0.5 to 1.5 microns and preferably about 1.0 micron.

With the insulating layers 25 in place, conductive vias 35 may be formed as shown in FIG. 4. The conductive vias 35 may be composed of a variety of conducting materials, such as copper, silver, aluminum, gold, platinum, palladium, combinations of these or the like. Various techniques may be used to establish the conductive vias 35, such as bias plating, electroless plating, CVD, physical vapor deposition (PVD), combinations of these techniques or the like. In an exemplary embodiment, copper may be deposited using a preliminary electroless plating process to establish a seed layer and a follow-on biased plating process to apply the remainder of the copper. Next, an interconnect structure 40 may be formed on the substrate 10 in ohmic contact with various of the conductive vias 35. The interconnect structure 40 may consist of one or more metallization layers, two of which are depicted schematically and labeled 45 and 50. The layers 45 and 50 may be electrically connected and interspersed with insulating material 55, which may consist of one or more layers of interlevel dielectric material such as silicon dioxide, TEOS, polymeric or other insulating materials.

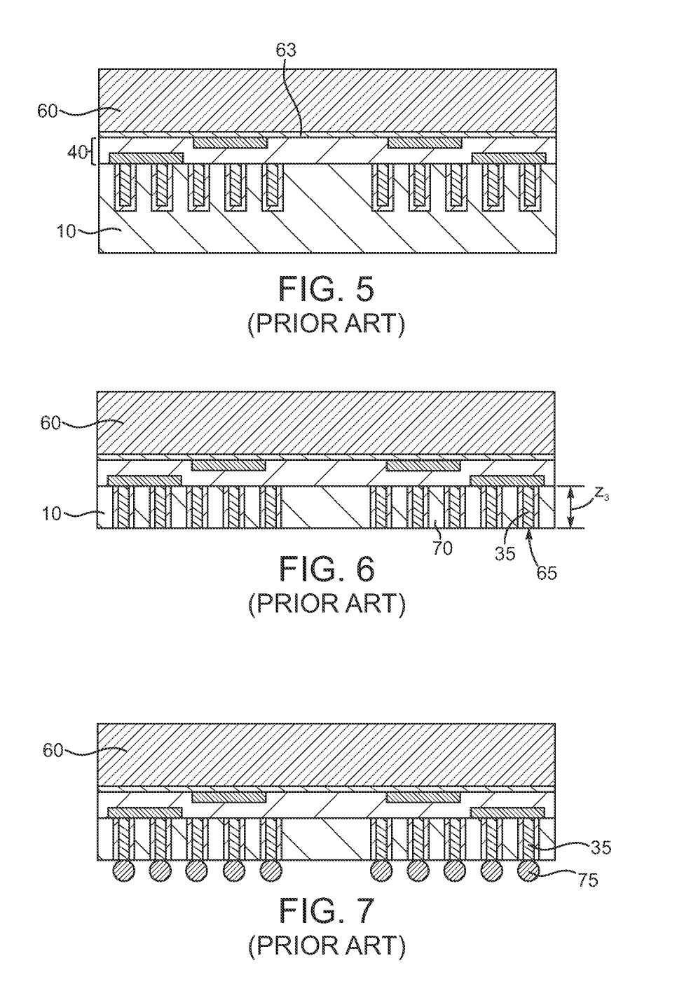

The conductive vias 35 are designed to ultimately function as TSVs. It should be understood that the term TSV as used herein is intended to include vias in substrates composed of not only silicon, but also other substrate materials. In order for the conductive vias 35 to function as TSVs, it is necessary to thin the substrate 10. To facilitate the handling of the substrate 10 during this thinning process and to protect the interconnect structure 40, a carrier substrate 60 may be secured to the interconnect structure as shown in FIG. 5. The carrier substrate 60 may be composed of various types of glasses, such as silicon dioxide, and may have a thickness in the range of about 450 to 550 microns. The carrier substrate 60 may be secured to the interconnect structure 40 by way of an adhesive 63 applied by spin coating or other techniques on the semiconductor wafer 10 and activated by UV or other stimulus.

As shown in FIG. 6, with the carrier substrate 60 in place, the substrate 10 may be thinned to expose lower ends 65 of the conductive vias 35. This thinning process may be performed using, for example, a lapping process. The post lapping thickness z₃ of the substrate 10 may be about 80 to 150 microns. At this stage, formation of active and/or routing circuitry in and about the interstices 70 of the substrate 10 may proceed. This circuit formation may include the multitudes of different processing steps used to fabricate active and passive circuit elements in semiconductor substrates using well-known processes.

Following any circuit formation, conductor structures 75 may be coupled to the vias 35 as depicted in FIG. 7 or circuits or other routing structures as the case may be. Here, the conductor structures 75 consist of solder bumps. However, other types of conductor structures, such as conductive pillars plus solder or other input/output type structures may be used. A variety of solders may be used such as various lead-based or lead-free solders. An exemplary lead-based solder may have a composition at or near eutectic proportions, such as about 63% Sn and 37% Pb. Lead-free examples include tin-silver (about 97.3% Sn 2.7% Ag), tin-copper (about 99% Sn 1% Cu), tin-silver-copper (about 96.5% Sn 3% Ag 0.5% Cu) or the like. The carrier substrate 60 may remain in place during the fabrication of active circuits and any input/output structures, such as the conductor structures 75.

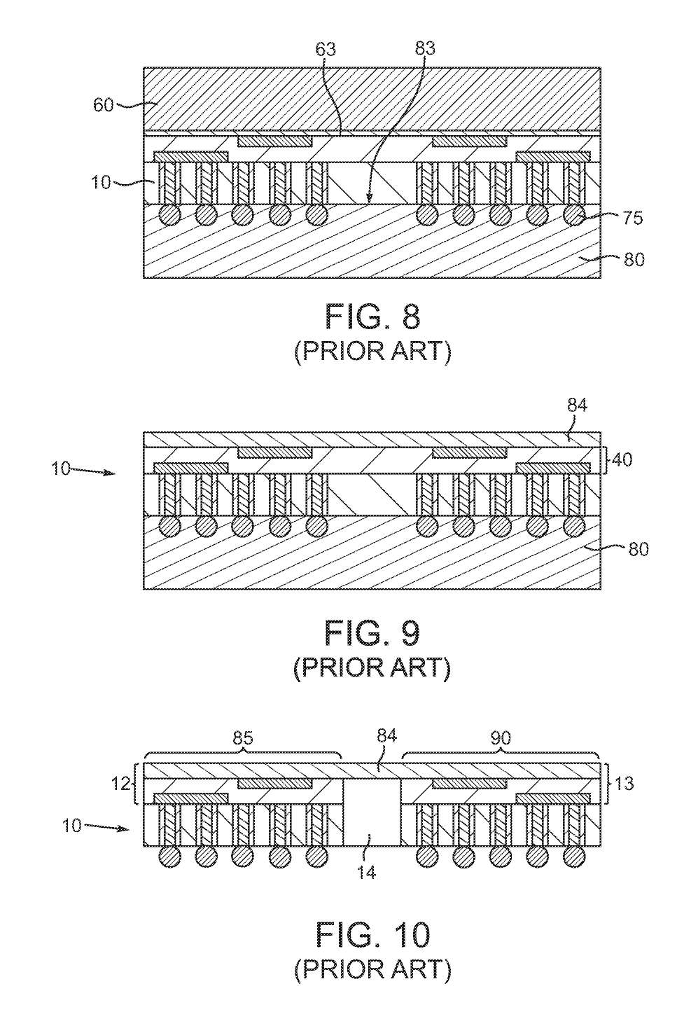

Referring now to FIG. 8, the carrier substrate 60 is intended to serve as a temporary supporting piece. In order to facilitate the removal of the carrier substrate 60 from the interconnect structure 40, another supporting substrate 80 is secured to the lower surface 83 of the substrate 10. The supporting substrate 80 may be an adhesive tape that includes an adhesive material that adheres to the lower surface 83 of the substrate 10 and effectively coats the conductor structures 75. Referring now also to FIG. 9, with the support substrate 80 in place, the carrier substrate 60 may be removed by laser debonding and peeling off the adhesive 63. As a prelude to singulation, a dicing tape 84 may be applied to the interconnect structure 40. The dicing tape 84 may be composed of well-known materials.

As shown in FIG. 10, the supporting substrate 80 is removed and the device regions 12 and 13 of the substrate 10 singulated along the dicing street 14 with the dicing tape 84 providing mechanical support. Here, the substrate 10 may be diced or otherwise cleaved by sawing, laser cutting or other material removal techniques. The singulation yields individual semiconductor devices 85 and 90. Only two semiconductor devices 85 and 90 are shown for simplicity of illustration. However, it should be understood that there may be scores or more of such devices. The semiconductor devices 85 and 90 may be peeled from or otherwise separated from the dicing tape 84 to yield singulated devices 85 and 90.

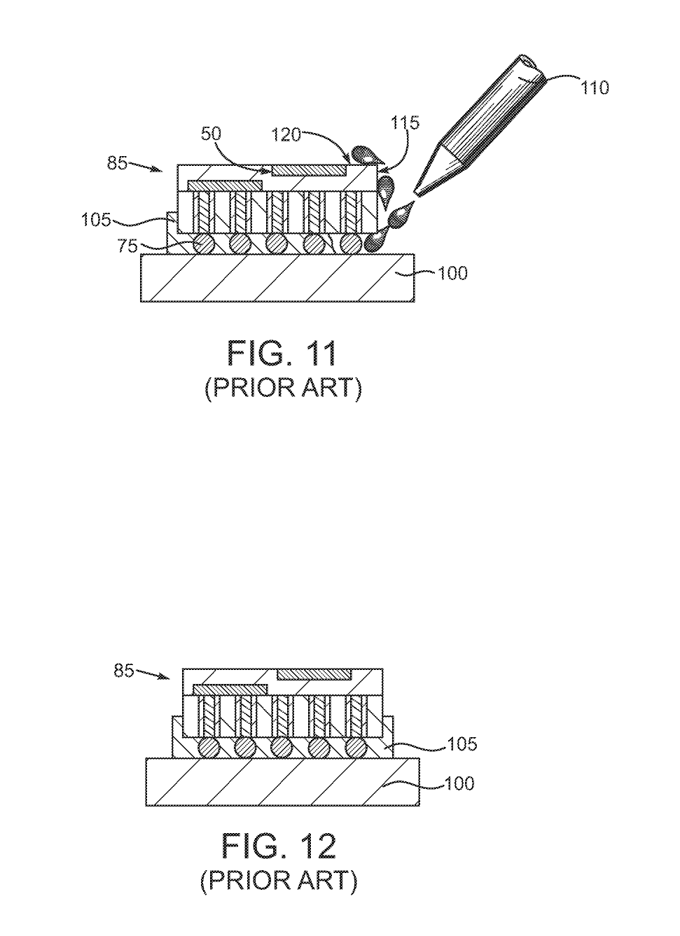

A given singulated device, such as the device 85, may be subsequently mounted to a circuit board 100 as shown in FIG. 11. This may entail a flip-chip mounting followed by a solder reflow of the conductor structures 75 to the circuit board 100. To lessen the effects of differences in CTE between the semiconductor device 85 and the circuit board 100, an underfill material 105 may be applied using a suitable applicator 110. One potential pitfall associated with the conventional process described thus far is that droplets of the underfill material 105 may progress up a sidewall 115 of the semiconductor device 85 and actually proceed across an upper surface 120 of the semiconductor device 85. If the underfill 105 encounters any exposed conductor, such as the portion 125 of the interconnect layer 45, then subsequent attempts to establish ohmic contact with that conductor portion 125 may be jeopardized.

As shown in FIG. 12, the underfill material 105 may undergo a bake process at about 150 to 165° C. for about an hour. At this stage, the semiconductor device 85 is mounted to the circuit board 100 and ready to receive other semiconductor devices in a 3-D stacked arrangement.

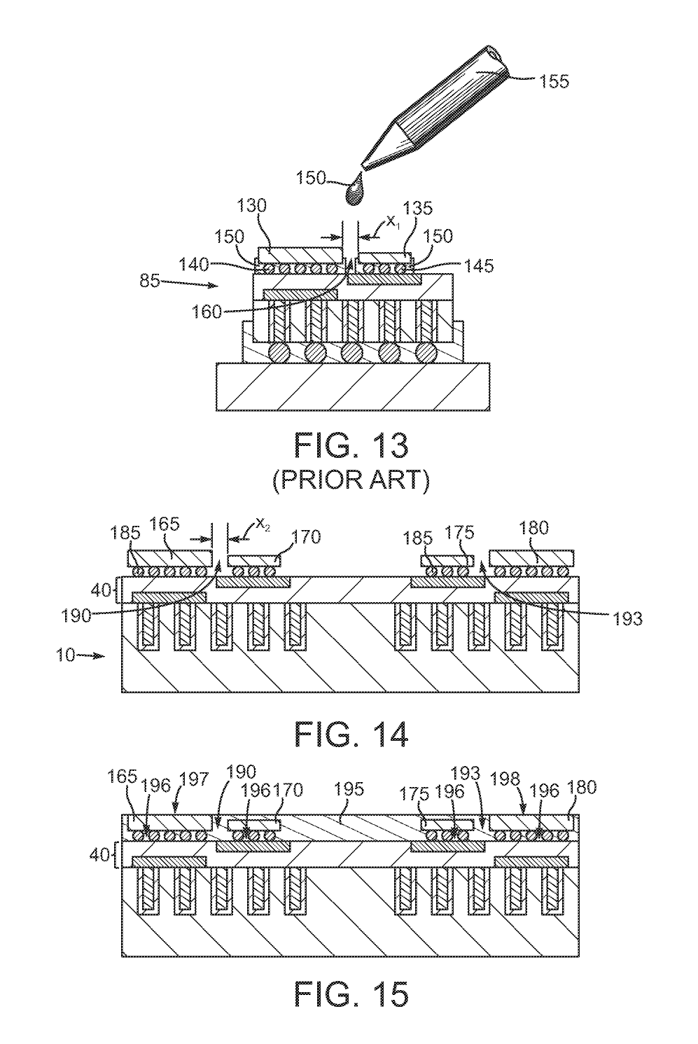

Referring now to FIG. 13, semiconductor chips 130 and 135 may be flip-chip mounted to the semiconductor device 85 and connected thereto by way of respective solder structures 140 and 145. An underfill material 150 may be interspersed between the semiconductor chips 130 and 135 and the semiconductor device 85 by way of a suitable applicator 155. Note that a gap 160 between the semiconductor chips 130 and 135 may be so narrow that the dispersal of the underfill 150 therein may proceed either slowly or result in the formation of air pockets.

An exemplary structure and method that overcomes some of the limitations associated with the conventional fabrication process just described may be understood by referring now to FIGS. 14, 15, 16, 17, 18 and 19 and initially to FIG. 14. Here, the substrate 10 may be processed as generally described above in conjunction with FIGS. 1-4. While in the conventional process described above in conjunction with FIGS. 1-5 would incorporate the usage of the aforementioned carrier substrate 60, this illustrative process obviates the use of a carrier substrate. Instead, at this stage multiple semiconductor chips 165, 170, 175 and 180 may be mounted to the interconnect structure 40 of the semiconductor chip 10. The semiconductor chips 165, 170, 175 and 180 may be composed of the types of materials disclosed elsewhere herein used to implement a great variety of different types of logic devices, such as, for example, microprocessors, graphics processors, combined microprocessor/graphics processors, application specific integrated circuits, memory devices or the like, and may be single or multi-core. Indeed the semiconductor chips 165, 170, 175 and 180 could even be implemented as interposers and/or composed of insulating materials. While only four semiconductor chips 165, 170, 175 and 180 are depicted for simplicity of illustration, it should be understood that there may be scores or more of such devices mounted to the interconnect structure 40. Similarly, while the semiconductor chips 165, 170, 175 and 180 may be flip-chip interconnected to the interconnect structure 40 by way of plural solder structures 185, other types of interconnect structures such as conductive pillars or others may be used instead. It should be noted that the semiconductor chips 165 and 180 are depicted with slightly larger thicknesses than the semiconductor chips 170 and 175. The skilled artisan will appreciate that various types of semiconductor dice may have different thicknesses depending upon the complexity of the active circuitry as well as both front and back side metallization layers.

The semiconductor chips 165 and 170 may be mounted with a lateral separation or space 190 of dimension x₂. The semiconductor chips 175 and 180 may be mounted with a lateral separation or space 193, which have dimension x₂ or some other dimension as desired. The exemplary method of applying an underfill to be described below enables the dimension x₂ to be smaller, if desired, than the conventional gap width x₁ depicted in FIG. 13.

Next, and as depicted in FIG. 15, an insulating layer 195 may be molded over the semiconductor chips 165, 170, 175 and 180 and to the interconnect structure 40. The insulating layer 195 thus serves dual roles of carrier substrate and underfill material. A molding process using a pressurized mold will not only ensure that the insulating layer 195 penetrates the gaps 196 between the semiconductor chips 165, 170, 175 and 180 and the interconnect structure 40 but also the spaces 190 and 193 between the chips 165 and 170 and 175 and 180, respectively. Thus, the spaces 190 and 193 may be smaller than the conventional process described above and thus be on the order of, for example, a millimeter or less. A variety of polymeric materials may be used for the insulating layer 195, such as various epoxies, with or without fillers. In an exemplary embodiment, an epoxy with silica filler may be used. A variety of parameters may be used for the molding process. In an exemplary embodiment, the insulating layer 195 may be molded at about 130° C. and a clamping force of about 100 kN. Following the molding, a bake process at about 150° C. for about one hour may be performed to harden the insulating layer 195. Here, the insulating layer 195 may be molded to be co-terminus with the upper surfaces 197 and 198, respectively, of the thicker semiconductor chips 165 and 180 or even thicker and thus overcoating those devices 165 and 180 as desired. If later processing requires the exposure of one or more of the semiconductor chips 165, 170, 175 and 180, then a thinning of the insulating layer 195 by lapping or other material removal processes may be performed.

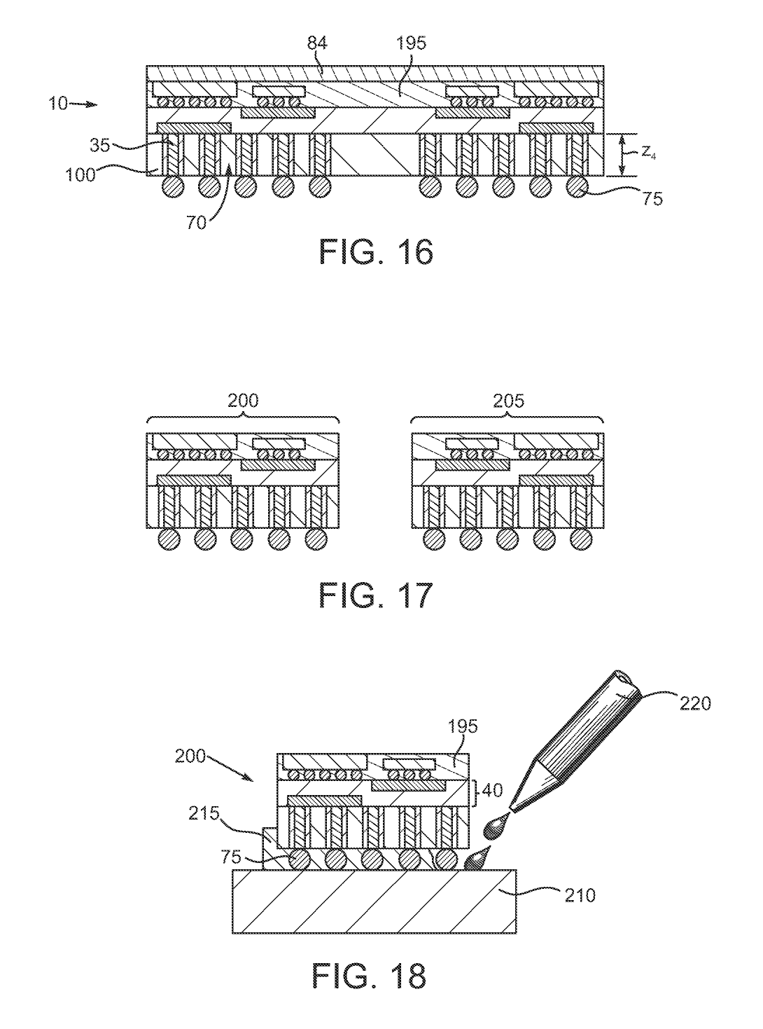

Next and as shown in FIG. 16, the substrate 10 may undergo thinning, circuit formation, and connection of conductor structures 75 as described generally above albeit with the insulating layer 195 serving as a carrier substrate in this regard. The circuit formation may include active and/or routing circuitry in and about the interstices 70 of the substrate 10. This circuit formation may include the multitudes of different processing steps used to fabricate active and passive circuit elements in semiconductor substrates using well-known processes. The thinning process may be performed using, for example, a lapping process. The post lapping thickness z₄ of the substrate 10 may be about 80 to 150 microns.

Following any circuit formation, conductor structures 75 may be coupled to the vias 35 as depicted in FIG. 16 or circuits or other routing structures as the case may be. As a prelude to singulation, the dicing tape 84 may be applied as described elsewhere herein. With the dicing tape 84 in place, singulation may be performed using any of the aforementioned techniques and the dicing tape 84 shown in FIG. 16 removed to yield individual semiconductor devices 200 and 205 as shown in FIG. 17. Again it should be understood that depending upon the size of the substrate 100 and the individual devices 200 and 205, the singulation process may produce many more than simply two semiconductor devices 200 and 205.

The semiconductor devices, say the device 200 for example, may be subsequently mounted to a circuit board 210 as shown in FIG. 18. This mounting may involve a solder reflow of the solder conductor structures 75 as described elsewhere herein followed by application of an underfill 215 by way of a suitable applicator 220. Here, the conductive structures of the interconnect structure 40 are already coated by the insulating layer 195 and thus the aforementioned potential difficulty associated with the underfill 215 creeping up a sidewall 225 of the semiconductor device 200 is alleviated. Furthermore, the enhanced thickness of the semiconductor device 200 over the conventional singulated device, say the device 85 described elsewhere herein, provides a greater mechanical strength during handling associated with the mounting to the circuit board 210. The circuit board 210 may be a semiconductor chip package substrate, a circuit card, or virtually any other type of printed circuit board. Although a monolithic structure could be used for the circuit board 210, a more typical configuration will utilize a buildup design. In this regard, the substrate 30 may consist of a central core of polymer materials upon which one or more buildup layers of polymer materials are formed and below which an additional one or more buildup layers of polymer materials are formed. Optionally, the circuit board 210 may be configured as an interposer composed of semiconductor or insulating materials.

FIG. 19 depicts the semiconductor device 200 mounted to the circuit board 210 following the application of the underfill 215 and a post application bake process. The bake process may be performed at about 150 to 165° C. for one hour, though these parameters will depend on, among various things, the material selected for the underfill 215 and the geometries of the circuit board 210 and the semiconductor device 200. At this stage, the circuit board 210 may be fitted with input/output structures 230, which may be solder balls, solder bumps, conductor pillars or other types of interconnect structures.

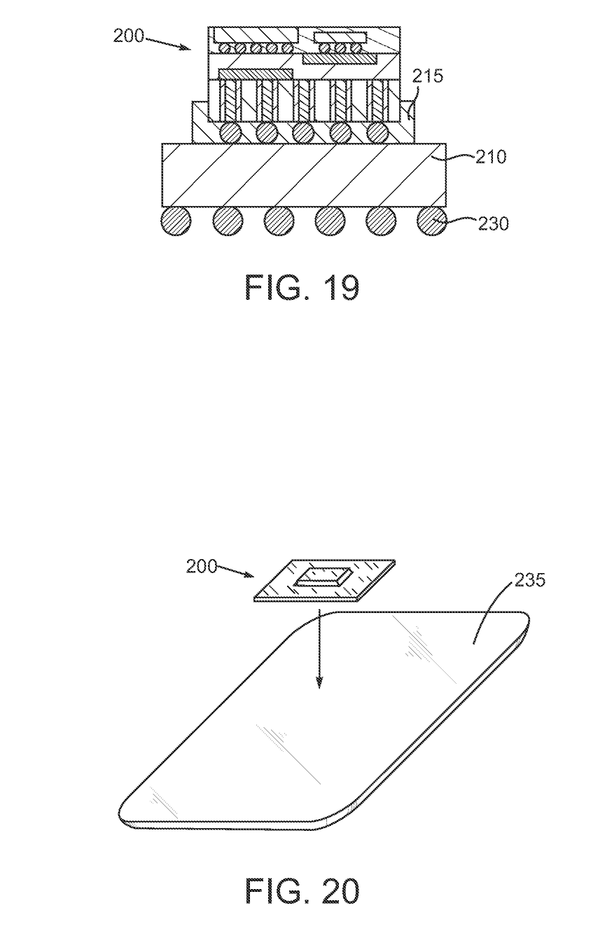

As shown in FIG. 20, which is a pictorial view, the semiconductor device 200 may be mounted to another electronic device 235, which may be a computer, a digital television, a handheld mobile device, a personal computer, a server, a memory device, an add-in board such as a graphics card, or any other computing device employing semiconductors.

Any of the exemplary embodiments disclosed herein may be embodied in instructions disposed in a computer readable medium, such as, for example, semiconductor, magnetic disk, optical disk or other storage medium or as a computer data signal. The instructions or software may be capable of synthesizing and/or simulating the circuit structures disclosed herein. In an exemplary embodiment, an electronic design automation program, such as Cadence APD, Encore or the like, may be used to synthesize the disclosed circuit structures. The resulting code may be used to fabricate the disclosed circuit structures.

While the invention may be susceptible to various modifications and alternative forms, specific embodiments have been shown by way of example in the drawings and have been described in detail herein. However, it should be understood that the invention is not intended to be limited to the particular forms disclosed. Rather, the invention is to cover all modifications, equivalents and alternatives falling within the spirit and scope of the invention as defined by the following appended claims.

What is claimed is:

1. A method of manufacturing, comprising:
mounting a first semiconductor chip on a side of a first substrate, the first substrate having at least one thru-silicon-via; and
molding an insulating layer on the side of the first substrate, the insulating layer providing a support structure to enable handling of the first substrate.

2. The method of claim 1, wherein the mounting comprises flip-chip mounting to leave a gap between the first semiconductor chip and the side of the first substrate, the molded insulating layer penetrating the gap to serve as an underfill.

3. The method of claim 1, comprising mounting a second semiconductor chip on the first side of the first substrate laterally separated from the first semiconductor chip by a space, the molded insulating layer filling the space and serving an underfill for the first and second semiconductor chips.

4. The method of claim 1, comprising planarizing the insulating layer to an upper side of the first semiconductor chip.

5. The method of claim 1, wherein the first substrate comprises a semiconductor wafer.

6. The method of claim 5, comprising singulating from the semiconductor wafer a portion of holding the first semiconductor chip.

7. The method of claim 6, comprising mounting the singulated portion to a second substrate.

8. The method of claim 7, wherein the second substrate comprises a circuit board.

9. The method of claim 1, comprising mounting the first substrate in an electronic device.

10. The method of claim 1, comprising thinning the first substrate.

11. A method of manufacturing, comprising:
forming a first group of thru-silicon-vias in a first portion of a semiconductor substrate and second group of thru-silicon-vias in a second portion of the semiconductor substrate, the semiconductor substrate having a side;
mounting a first semiconductor chip on the side and first portion of the semiconductor substrate;
mounting a second semiconductor chip on the side and second portion of the semiconductor substrate;
molding an insulating layer on the side of the semiconductor substrate, the insulating layer providing a support structure to enable handling of the semiconductor substrate.

12. The method of claim 11, wherein the mounting comprises flip-chip mounting to leave a first gap between the first semiconductor chip and the side and a second gap between the second semiconductor chip and the side, the molded insulating layer penetrating the first and second gaps to serve as an underfill.

13. The method of claim 11, comprising mounting a third second semiconductor chip on the side of the semiconductor substrate laterally separated from the first semiconductor chip by a space, the molded insulating layer filling the space and serving an underfill for the first and third semiconductor chips.

14. The method of claim 11 comprising planarizing the insulating layer to an upper side of an outermost projecting of the first and third semiconductor chips.

15. The method of claim 11, wherein the semiconductor substrate comprises a semiconductor wafer.

16. The method of claim 11, comprising singulating from the semiconductor substrate the first portion holding the first semiconductor chip.

17. An apparatus, comprising:
a substrate including at least one thru-silicon-via, a side and a dicing street;
a first semiconductor chip coupled to the side of the substrate on a side of the dicing street and a second semiconductor chip coupled to the side on an opposite side of the dicing street; and
an insulating layer on the side of the substrate and spanning across the dicing street, the insulating layer serving as an underfill for the first and second semiconductor chips and providing a support structure to enable handling of the substrate.

18. The apparatus of claim 17, wherein the first and second semiconductor chips are flip-chip mounted to the side of the substrate.

19. The apparatus of claim 17, comprising a third second semiconductor chip coupled to the side of the substrate on the side of the dicing street and laterally separated from the first semiconductor chip by a space, the insulating layer filling the space and serving an underfill for the first and third semiconductor chips.

20. The apparatus of claim 17, wherein the substrate comprises a semiconductor wafer.
